(19) United States
(12) Patent Application Publication
(10) Pub. No.: US 2016/0024650 A1
(43) Pub. Date: Jan. 28, 2016

(54) SUBSTRATE PROCESSING APPARATUS

(71) Applicant: HITACHI KOKUSAI ELECTRIC INC., Toyama-shi (JP)

(72) Inventors: Kazuyuki TOYODA, Toyama-shi (JP); Hiroshi ASHIHARA, Toyama-shi (JP); Atsushi SANO, Toyama-shi (JP); Naonori AKAE, Toyama-shi (JP); Hidehiro YANAI, Toyama-shi (JP)

(73) Assignee: HITACHI KOKUSAI ELECTRIC INC., Toyama-shi (JP)

(21) Appl. No.: 14/804,653

(22) Filed: Jul. 21, 2015

(30) Foreign Application Priority Data
Jul. 22, 2014 (JP) 2014-148875

(51) Int. Cl. C23C 16/44; C23C 16/458; C23C 16/455; C23C 16/52

(52) U.S. Cl. CPC C23C 16/4409; C23C 16/52; C23C 16/4583; C23C 16/45523

(57) ABSTRACT

A substrate processing apparatus includes: a reaction zone configured to accommodate a substrate; a substrate supporting member having a projecting part extending outward; a partition plate configured to partition off the reaction zone and a transferring zone, coming in contact with the projecting part of the substrate supporting member when the substrate is processed; a process gas supplying system configured to supply a process gas to the reaction zone; and a partitioning purge gas supplying system configured to supply a purge gas to a gap formed between the projecting part and the partition plate when supplying the process gas to the substrate.

### CROSS-REFERENCE TO RELATED APPLICATION

This application claims benefit of Japanese Patent Application No. 2014-148875, filed on Jul. 22, 2014, which is herein incorporated by reference in its entirety.

### TECHNICAL FIELD

The present disclosure provides a substrate processing apparatus, a method of manufacturing a semiconductor device, a non-transitory computer-readable recording medium storing a program for manufacturing a semiconductor device by employing the substrate processing apparatus.

### BACKGROUND

According to the high integration of Large Scale Integrated Circuit (hereinafter LSI), the miniaturization of the circuit pattern is pushed forward.

To integrate many semiconductor devices in a narrow area of the substrate, the size of each semiconductor device should be small, then the width of wiring pattern and the distance of the wiring pattern should be reduced.

By recent miniaturization, film formation to the microstructure on the substrate, especially to form a film in perpendicularly deep groove or laterally narrow cavity may be reaching to the technical limit. In addition, the formation of a thin, uniform film is required by miniaturization of the transistor. Furthermore, shortening of the processing time around one piece of substrate is demanded to raise the productivity of the semiconductor device.

In addition, to improve the productivity of the semiconductor device, in-plane uniformity of the substrate is demanded.

Since the smallest processing dimensions for LSI becomes smaller than 30 nm width recently, and the film thickness becomes thinner, it becomes difficult to improve the production throughput and uniformity of the film formed on the substrate with maintaining a good quality.

In this disclosure, a substrate processing apparatus, a method of manufacturing a semiconductor device and a non-transitory computer-readable recording medium storing a program for manufacturing a semiconductor device are disclosed.

### SUMMARY

According to the present disclosure, there is provided a substrate processing apparatus which includes: a reaction zone configured to accommodate a substrate; a substrate supporting member having a projecting part extending outward; a partition plate configured to partition off the reaction zone and a transferring zone, coming in contact with the projecting part of the substrate supporting member when the substrate is processed; a process gas supplying system configured to supply a process gas to the reaction zone; and a partitioning purge gas supplying system configured to supply a purge gas to a gap formed between the projecting part and the partition plate when supplying the process gas to the substrate.

According to another disclosure, there is provided a method of manufacturing a semiconductor device which includes: accommodating a substrate in a reaction zone; supporting the substrate by employing a substrate supporting member having a projecting part extending outward; and supplying a purge gas to a gap formed between the projecting part and a partition plate, the partition plate being configured to partition off the reaction zone and a transferring zone, coming in contact with the projecting part when the substrate is processed.

Pursuant to another disclosure, there is provided a non-transitory computer-readable recording medium storing a program for manufacturing a semiconductor device by employing the substrate processing apparatus, the program causing the substrate processing apparatus to execute: accommodating a substrate in a reaction zone; supporting the substrate by employing a substrate supporting member having a projecting part extending outward; and supplying a purge gas to a gap formed between the projecting part and a partition plate, the partition plate being configured to partition off the reaction zone and a transferring zone, coming in contact with the projecting part when the substrate is processed.

According to the substrate processing apparatus, the method of manufacturing a semiconductor device or the non-transitory computer-readable recording medium storing a program for manufacturing a semiconductor device in the present disclosure, it may be possible to improve the production throughput and uniformity of the film formed on the substrate with maintaining a good quality.

### BRIEF DESCRIPTION OF THE DRAWINGS

FIG. 1 is a conception diagram of a substrate processing apparatus according to a first embodiment of the present disclosure.

FIG. 2 is a schematic view showing positional relations of substrate setting tray and partitioning plate under processing.

FIG. 3A is a top view of a partition plate according to the first embodiment of the present disclosure. A purge gas supply path and a purge gas supply groove, not to see from top side, are disclosed in dashed lines for understanding.

FIG. 3B is a cross-sectional view of the partition plate and partitioning gas system according to the first embodiment of the present disclosure.

FIG. 3C is a side view of the partition plate according to the first embodiment of the present disclosure.

FIG. 3D is a bottom view of the partition plate according to the first embodiment of the present disclosure. A purge gas supply path, not to see from bottom side, is disclosed in dashed lines for understanding.

FIG. 4A is a cross-sectional view of the partition plate and partitioning gas system according to another embodiment of the present disclosure.

FIG. 4B is a bottom view of the partition plate according to another embodiment of the present disclosure. A purge gas supply path, not to see from bottom side, is disclosed in dashed lines for understanding.

FIG. 5A is a top view of a substrate setting tray according to another embodiment of the present disclosure. A purge gas supply path, not to see from top side, are disclosed in dashed lines for understanding.

FIG. 5B is a cross-sectional view of the substrate setting tray according to another embodiment of the present disclosure.

FIG. 6 is a schematic view of the configuration of the controller of the substrate processing apparatus according to an embodiment of the present disclosure.

FIG. 7 is a figure of sequence of a substrate processing process.

FIG. 8A is a schematic view showing positional relation of substrate setting tray and partitioning plate under processing a wafer according to another embodiment of the present disclosure.

FIG. 8B is a schematic view showing positional relation of substrate setting tray and partitioning plate under transferring a wafer according to another embodiment of the present disclosure.

FIG. 9A is a schematic view showing positional relation of substrate setting tray and partitioning plate under transferring a wafer according to another embodiment of the present disclosure.

FIG. 9B is a schematic view showing positional relation of substrate setting tray and partitioning plate under processing a wafer according to another embodiment of the present disclosure.

FIG. 9C is a schematic view showing positional relation of substrate setting tray and partitioning plate under processing a wafer according to another embodiment of the present disclosure.

### DETAILED DESCRIPTION

Hereinafter, embodiments of the present disclosure will be described.

### The First Embodiment of the Present Disclosure

Hereinafter, the first embodiment of the present disclosure will be described with reference to the drawings.

(1) Configuration of a substrate processing apparatus Firstly, a substrate processing apparatus according to the first embodiment will be described.

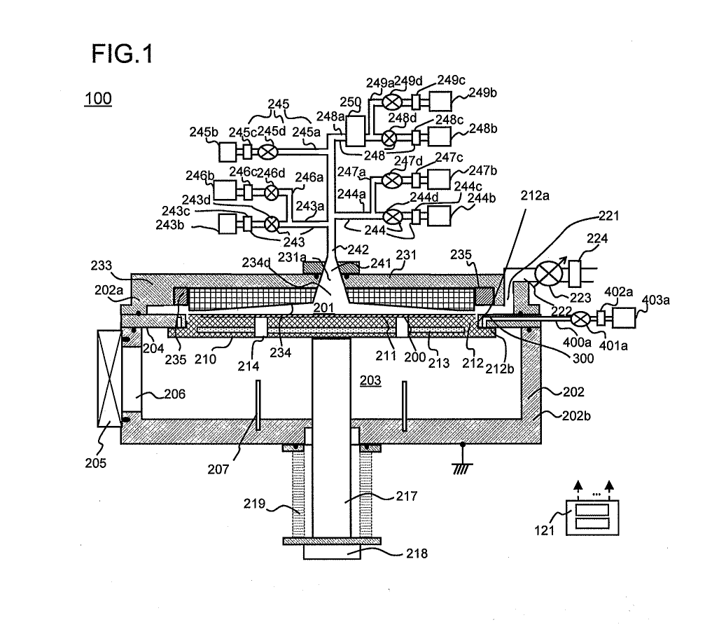

Configuration of substrate processing apparatus 100 according to the first embodiment will be described. Substrate processing apparatus 100 is an apparatus for forming films including insulating films or metal films on a substrate. As shown in FIG. 1, substrate processing apparatus 100 is configured to process a substrate one by one.

As shown in FIG. 1, substrate processing apparatus 100 includes process chamber 202. Process chamber 202 may be configured to be an airtight container having a flat structure to accommodate a substrate under the state that the principal plane of the substrate keeps horizontally. For example, process chamber 202 may be made of metal materials such as aluminum (Al) or the stainless steel (SUS) or quartz. Reaction zone 201 (reaction room) for processing wafer 200 as a substrate and transfer zone 203 may be formed in process chamber 202. Process chamber 202 includes upper part container 202a and lower part container 202b. Partition plate 204 is disposed between upper part container 202a and lower part container 202b. The space surrounded by upper part container 202a and located more upward than partition plate 204 is called reaction zone 201. The space surrounded by lower part container 202b and located more downward than partition plate 204 is called transfer zone 203.

Substrate I/O port 206 may be disposed at the side wall of lower part container 202b, adjacent to gate valve 205. Wafer 200 moves from transport chamber (not shown) to transfer zone 203 via substrate I/O port 206 or moves transfer zone 203 to transport chamber (not shown) via substrate I/O port 206. In the bottom of lower part container 202b, a plurality of lift pins may be disposed. Furthermore, lower part container 202b may be grounded electrically.

Substrate supporting member 210 for supporting wafer 200 is arranged in reaction zone 201. Substrate supporting member 210 may include substrate receiving surface 211 for placing wafer 200, substrate setting tray 212 having substrate receiving surface 211 on the top surface, heater 213 as a heating member being contained by substrate setting tray 212. Through-holes 214 which lift pins 207 can penetrate may be established at the specific positions in substrate setting tray 212, the specific positions are corresponding to the positions of lift pins 207 standing up from a bottom part of lower container 202b.

Side wall 212a of substrate setting tray 212 has projecting part 212b extending outward from substrate setting tray 212 in the radial direction. Projecting part 212b may be disposed in the bottom side of substrate setting tray 212. Mention it later, when substrate setting tray 212 is elevated for processing wafer 200, projecting part 212b may contact with partition plate 204 so as to reduce the leakages of gas from reaction zone 201 to transfer zone 203, or from transfer zone 203 to reaction zone 201.

Substrate setting tray 212 may be supported by shaft 217. Shaft 217 may penetrate a bottom of process chamber 202, being connected with lifting mechanism 218 at the outside of process chamber 202. It is possible that wafer 200 placed on substrate receiving surface 211 is moved up and down by elevating shaft 217 and substrate setting tray 212 under operating lifting mechanism 218. Reaction zone 201 may be kept airtight by covering with bellows 219 around a lower end portion of shaft 217.

When wafer 200 is being transferred, substrate receiving surface 211 on substrate setting tray 212 moves down to the position corresponding to substrate I/O port 206, named “position for transferring substrate”, and this position is maintained during transferring wafer 200. When wafer 200 is being processed, substrate receiving surface 211 on substrate setting tray 212 moves up to the position as shown in FIG. 1, named “position for processing substrate”, and this position is maintained during processing wafer 200.

Specifically, when substrate setting tray 212 is moved down to the position for transferring substrate, upper end portions of lift pins 207 protrude from substrate receiving surface 211 so that lift pins 207 can support wafer 200 from below. Also, when substrate setting tray 212 is moved up to the position for processing substrate, lift pins 207 are buried under substrate receiving surface 211 so that substrate receiving surface 211 can support wafer 200 from below. Since the tops of lift pins 207 come into contact with wafer 200 directly, at least the tops of lift pins 207 are preferably made of the material such as quartz or alumina.

Exhaust port 221 for exhausting gases in reaction zone 201 may be arranged at the position of the side wall of upper part container 202a so as to exhaust the gases horizontally. Ina horizontal direction, exhaust port 221 may be located in the outside beyond a connected part between substrate setting tray 212 and partition plate 204 when substrate setting tray 212 comes into contact with partition plate 204 under the state that substrate setting tray 212 is located at the position for processing substrate. Exhaust conduit 222 is connected to exhaust port 221, being connected to pressure regulator 223 such as an APC (Auto Pressure Controller) so as to control the pressure in reaction zone 201 to predetermined pressure, being connected to vacuum pump 224 in series. Mainly, exhaust system 220 may include exhaust port 221, exhaust conduit 222 and pressure regulator 223. In addition, vacuum pump 224 can be added to exhaust system 220 as a part of its configuration.

(Gas Introducing Port)

Gas introducing port 241 may be arranged to the upper surface (Ceiling wall) of gas expanding channel 234 which is disposed at the upper part of reaction zone 201. Various gases may be supplied to reaction zone 201 through gas introducing port 241. The configuration of gas supply system connected to gas introducing port 241 is described later.

(Gas Expanding Channel)

Gas expanding channel 234 may be disposed between gas introducing port 241 and reaction zone 201. Gas expanding channel 234 includes at least opening 234d for process gas to go through it. Gas expanding channel 234 may be attached to lid 231 by attachment 235. The gases introduced from gas introducing port 241 may be supplied to wafer 200 via aperture 231a and gas expanding channel 234. Gas expanding channel 234 may be defined by a part of the side wall of lid 231. Gas expanding channel 234 may be extending along a vertical axis on the center of principal surface of wafer 200 on substrate receiving surface 211. Gas expanding channel 234 may have a tapered bottom surface, being shaped and sized to substantially cover wafer 200 on substrate receiving surface 211, so that the gases can be dispersed to the entire principal surface of wafer 200.

When the process gas is supplied to reaction zone 201, there may occur minute gap 500g between projecting part 212b of substrate setting tray 212 and partition plate 204. Therefore, the process gas may leak from reaction zone 201 to transfer zone 203 through gap 500g. The process gas existing in gap 500g may cause the pressure rise in gap 500g, which forces substrate setting tray 212 so as to push down to the side of transfer zone 203, under the state that process gas is supplied to reaction zone 201. The gas leaked from reaction zone 201 to transfer zone 203 through gap 500g may adhere to the inner wall defining transfer zone 203 or some parts including lift pins 207 or bellows 219. In the event that wafer 200 is transferring, the pressure or temperature in transfer zone 203 or reaction zone 201 is drastically changed, the films or byproducts adhered to the inner wall defining transfer zone 203 may come off the wall and adhere to wafer 200. We disclose that partitioning gas system. 300 for supplying purge gas to the gap 500g which may be generated between projecting part 212b of substrate setting tray 212 and partition plate 204 when projecting part 212b is going to come into contact with partition plate 204 under processing wafer 200. By supplying a purge gas to gap 500g, the pressure in gap 500g becomes higher. Therefore, the gas leaks from reaction zone 201 to gap 500g or transfer zone 203 to gap 500g are cut off. In addition, gap 500g may be caused by the difference of flatness or horizontal degree between the top surface of projecting part 212b of substrate setting tray 212 and the bottom surface of partition plate 204. Gap 500g may include an area where projecting part 212b of substrate setting tray 212 does not come into contact with partition plate 204 partly in the circumferential direction of substrate setting tray 212.

In addition, gap 500g is easy to produce in the case such as process gases are supplied to reaction zone 201 alternately, or such as process gases are supplied to reaction zone 201 using gas expanding channel 234. When process gases, including a first process gas and a second process gas, are supplied to reaction zone 201 alternately, using a first gas supply system and a second gas supply system to mention later, the changes of the gases are repeated many times. Therefore, by arranging partitioning gas system 300, gas flows from reaction zone 201 to transfer zone 203 through gap 500g can be cut off, thus, forming films or producing byproducts on the wall defining transfer zone 203 can be reduced. In the case of the substrate processing apparatus having gas expanding channel 234, process gases are delivered to reaction zone 201 rapidly. Therefore, partitioning gas system 300 may work to cut off the gases effectively. Exhaust port 221 for exhausting gases in reaction zone 201 may be arranged at the position of the side wall of upper part container 202a so as to exhaust the gases horizontally. In a horizontal direction, exhaust port 221 may be located in the outside beyond a connected part between substrate setting tray 212 and partition plate 204 when substrate setting tray 212 comes into contact with partition plate 204 under the state that substrate setting tray 212 is located at the position for processing substrate as shown in FIG. 1. Thus, process gases introduced from gas expanding channel 234 may be delivered to wafer 200 directly, without via a buffering part for flowing gases like a showerhead (not illustrated), then the gases may be exhausted almost horizontally beyond a connected part between substrate setting tray 212 and partition plate 204 to exhaust port 221. And the flow rate of the gases getting closer to exhaust port 221 may be accelerated by the venturi effect due to a tapered bottom surface of gas expanding channel 234. On this occasion, the gases may be apt to flow into transfer zone 203 through gap 500g. Therefore, partitioning gas system 300 for gap 500g at the border may work to cut off the gases effectively.

(Partitioning Gas System)

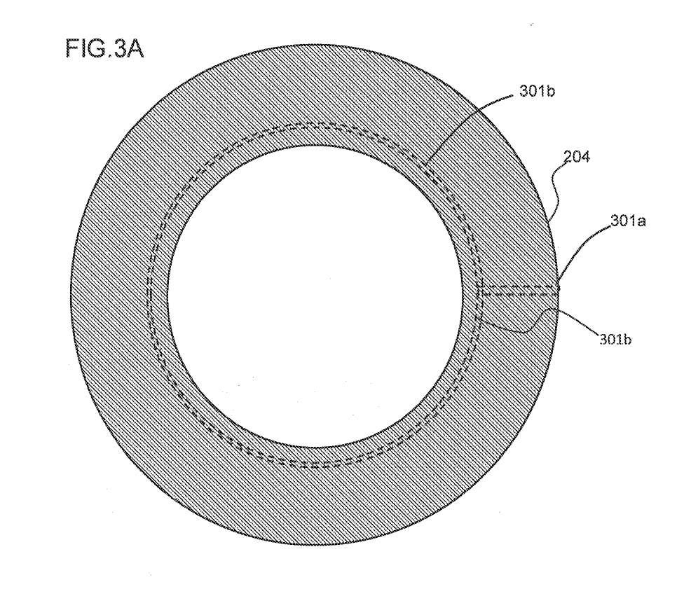

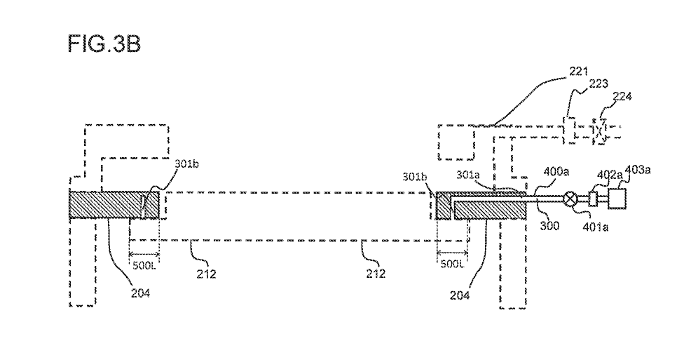

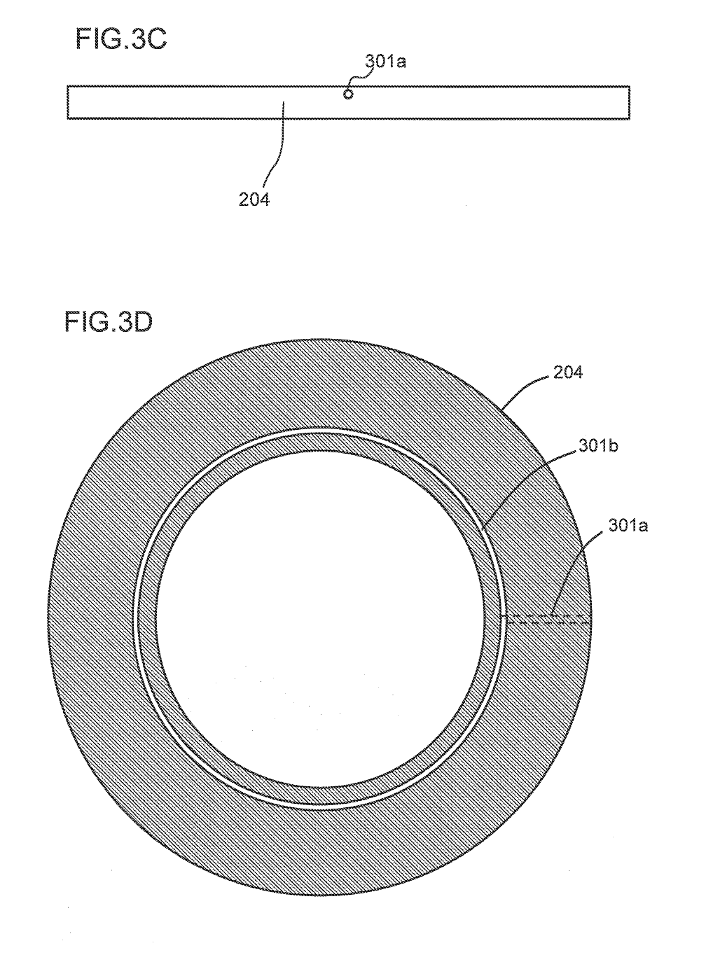

Partitioning gas system 300 is described with reference to FIG. 3A, FIG. 3B, FIG. 3C or FIG. 3D.

As shown in FIGS. 3B and 3C, purge gas supply path 301a and purge gas supply groove 301b may be formed in partition plate 204. Purge gas supply path 301a may be connected to purge gas supply groove 301b in partition plate 204. Purge gas supply groove 301b may be disposed concentrically on the bottom surface of partition plate 204. The edge of purge gas supply groove 301b may be arranged to the contact area between partition plate 204 and projecting part 212b. The width of the radial direction of purge gas supply groove 301b may be controlled within the width of the radial direction of the contact area between partition plate 204 and projecting part 212b. Purge gas supply conduit 400a may be connected to purge gas supply path 301a, being connected to valve 401a, mass flow controller (MFC) 402a and purge gas supply source 403a. After the flow quantity of purge gas generated in purge gas supply source 403a is regulated in mass flow controller 402a, the purge gas is delivered to purge gas supply groove 301b through valve 401a, Purge gas supply conduit 400a and purge gas supply path 301a.

Partitioning gas system 300 includes purge gas supply path 301a and purge gas supply groove 301b. Purge gas supply conduit 400a, valve 401a or mass flow controller 402a may be included to partitioning gas system 300. In addition, purge gas supply source 403a may be further included to partitioning gas system 300.

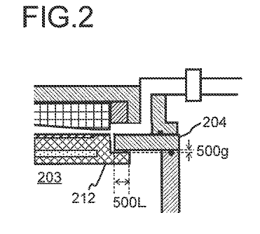

As shown in FIG. 2, gap 500g may be occurred at contact area 500L between partition plate 204 and projecting part 212b. In the event that the length of the radial direction of contact area 500L is longer appropriately than the vertical width of gap 500g, the space having high pressure can be generated in gap 500g under delivering the purge gas to gap 500g via partitioning gas system 300. The pressure in the space of gap 500g becomes higher than that of reaction zone 201 or transfer zone 203, therefore the gas flows from reaction zone 201 to gap 500g or from transfer zone 203 to gap 500g can be cut off. In this way, the process gas leak to transfer zone 203 can be reduced, thus, production of byproducts or particles can be reduced.

In addition, it is preferable for the length of the radial direction of contact area 500L to be more than 10 times of the vertical width of gap 500g. More preferably, the length of the radial direction of contact area 500L to be more than 100 times of the vertical width of gap 500g. More preferably, the length of the radial direction of contact area 500L to be more than 1,000 times of the vertical width of gap 500g. Exhaust conductance “C” of gap 500g is represented in the following formula as a simplified.

C=a×ĝ2/L

In this formula, “C” means an exhaust conductance of gap 500g, “a” means a fixed numeric constant, “g” means vertical width of gap 500g, “L” means the length of the radial direction of contact area 500L. As shown in this formula, when “g” is shorter than “L”, “C” (the exhaust conductance of gap 500g) can be made smaller, then, gas flow from reaction zone 201 to transfer zone 203 can become hard. Therefore, the gas leak from reaction zone 201 to transfer zone 203 can be reduced. Since the exhaust conductance of gap 500g becomes low, when the pressure in reaction zone 201 is lower than the pressure in transfer zone 203 by exhausting reaction zone 201 for a vacuum, the gas flow from transfer zone 203 to reaction zone 201 can be reduced. Therefore, it is restrained that the byproducts or particles including metallic materials existing in transfer zone 203 flow into reaction zone 201.

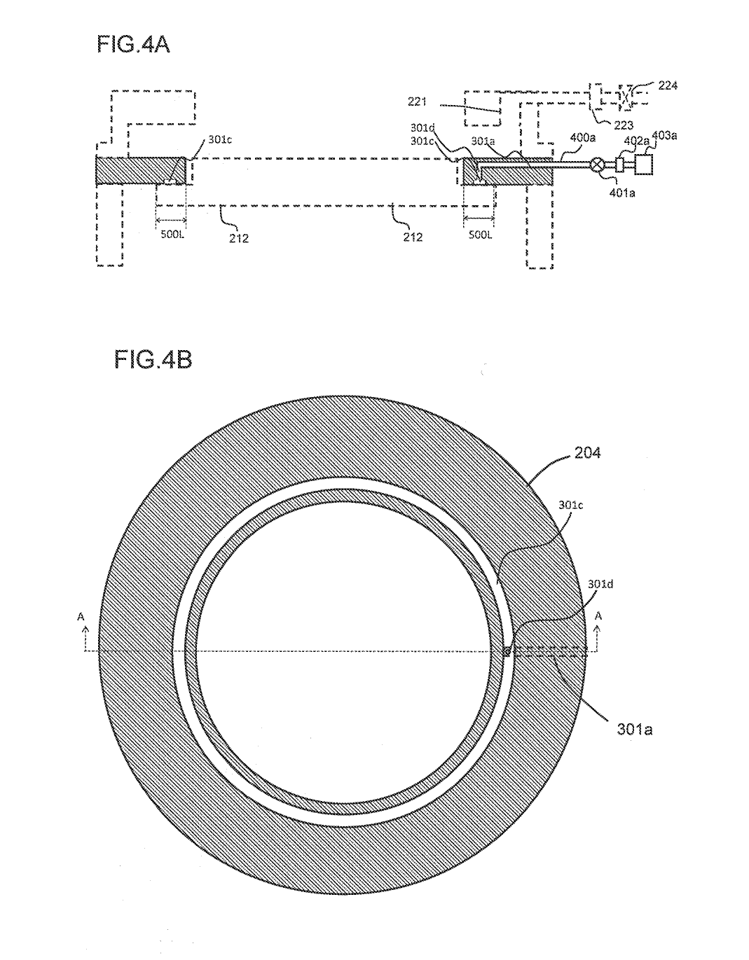

In addition, partitioning gas system 300 can be configured as shown in FIG. 4A and FIG. 4B. Buffer groove 301C may be formed in partition plate 204, being connected to purge gas supply path 301a via additional supply path 301d. Buffer groove 301C may have the opening which is facing to contact area 500L. The width of the opening in the radial direction may be defined more widely than the width of additional supply path 301d for forming an effective buffer space, but within the width of contact area 500L. By disposing buffer groove 301C in partition plate 204, the purge gas can be delivered uniformly to the whole circumference of the top surface of projecting part 212b of substrate setting tray 212. Therefore, gas leak areas where the gases may be leaked from reaction zone 201 to transfer zone 203 can be reduced.

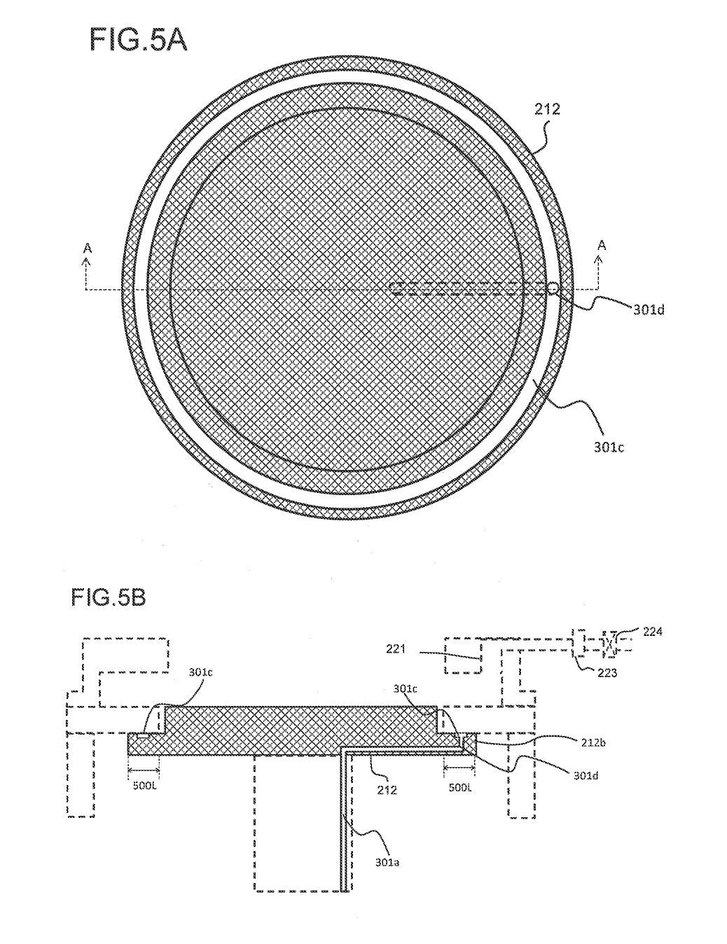

In addition, partitioning gas system 300 can be configured as shown in FIG. 5A and FIG. 5B. Buffer groove 301C may be formed in projecting part 212b, being connected to purge gas supply path 301a via additional supply path 301d in substrate setting tray 212. Buffer groove 301C may have the opening which is facing to contact area 500L. The width of the opening in the radial direction may be defined more widely than the width of additional supply path 301d for forming an effective buffer space, but within the width of contact area 500L. By disposing buffer groove 301C in projecting part 212b, the purge gas can be delivered uniformly to the whole circumference of the bottom surface of partition plate 204. Therefore, gas leak areas where the gases may be leaked from reaction zone 201 to transfer zone 203 can be reduced.

(Process Gas Supply System)

Gas introducing port 241 connected to gas expanding channel 234 may be connected to shared gas supply conduit 242. Shared gas supply conduit 242 may be coupled with first gas supply conduit 243a, second gas supply conduit 244a, third gas supply conduit 245a or cleaning gas supply conduit 248a.

The gas containing first element (first process gas) may be delivered to shared gas supply conduit 242 through first gas supply system 243 including first gas supply conduit 243a. The gas containing second element (second process gas) may be delivered to shared gas supply conduit 242 through second gas supply system 244 including second gas supply conduit 244a. A purge gas may be delivered to shared gas supply conduit 242 through third gas supply system 245 including third gas supply conduit 245a. A cleaning gas may be delivered to shared gas supply conduit 242 through cleaning gas supply system 248 including cleaning gas supply conduit 248a. Process gas supply system for delivering process gas(es) may be configured by either first gas supply system 243 or second gas supply system 244, or both first gas supply system 243 and second gas supply system 244. Similarly, process gas(es) mean(s) either or both the first gas and the second gas.

(First Gas Supply System)

In first gas supply conduit 243a, first gas supply source 243b, mass flow controller (MFC) 243c and valve 243d may be sequentially arranged from the upstream side.

The gas containing first element (first process gas) may be supplied from first gas supply source 243b, then, the gas containing first element may be delivered to gas expanding channel 234 via mass flow controller 243c and valve 243d, through first gas supply conduit 243a and shared gas supply conduit 242.

The gas containing first element (first process gas) may be one of process gases including a source gas or a precursor gas. For example, the first element is silicon (Si). That is to say, for instance, the first process gas is the gas containing silicon. Dichlorosilane (SiH₂Cl₂:DCS) gas can be adapted to the gas containing silicon. In addition, the raw material of the first process gas may be a solid, a liquid or gaseous state in normal temperature ordinary pressure. In the event that the raw material of the first process gas is a liquid in normal temperature ordinary pressure, a vaporizer (not shown) may be disposed on the pathway between first gas supply source 243b and mass flow controller 243c. Hereinafter, the embodiments are disclosed under the state that the raw material of the first process gas is gaseous state in normal temperature ordinary pressure.

The edge of the downstream side of first inert gas supply conduit 246a may be coupled with the downstream side from valve 243d arranged in first gas supply conduit 243a. Inert gas supply source 246b, mass flow controller (MFC) 246c and valve 246d may be sequentially arranged from the upstream side in first inert gas supply conduit 246a.

The inert gas may act as a carrier gas for the first process gas, not reacting with the first process gas. For example, the inert gas may be nitrogen (N₂) gas. Other than nitrogen (N₂) gas, a rare gas such as helium (He) gas, neon (Ne) gas or argon (Ar) gas etc. may be used.

First gas supply system 243 may include first gas supply conduit 243a, mass flow controller 243c and valve 243d.

First inert gas supply system may include first inert gas supply conduit 246a, mass flow controller 246c and valve 246d. In addition, inert gas supply source 246b or first gas supply conduit 243a can be included to the first inert gas supply system.

Furthermore, first gas supply source 243b or first inert gas supply system can be included to first gas supply system 243.

(Second Gas Supply System)

In second gas supply conduit 244a, second gas supply source 244b, mass flow controller (MFC) 244c and valve 244d may be sequentially arranged from the upstream side.

The gas containing second element (second process gas) may be supplied from second gas supply source 244b, then, the gas containing second element may be delivered to gas expanding channel 234 via mass flow controller 244c and valve 244d through second gas supply conduit 244a and shared gas supply conduit 242.

The gas containing second element (second process gas) may be one of process gases including a reactant gas or a conversion gas.

Here, the second process gas may contain the second element unlike the first element. The second element may contain at least one or more atoms selected from the group consisting of oxygen atom (O), nitrogen atom (N), carbon atom (C) or hydrogen atom. In this embodiment, for example, the second process gas may be the gas containing nitrogen. Specifically, for the gas containing nitrogen, ammonia (NH3) gas may be used.

Second gas supply system 244 may include second gas supply conduit 244a, mass flow controller 244c and valve 244d.

The edge of the downstream of second gas supply conduit 247a may be coupled with the downstream side from valve 244d arranged in second gas supply line 244a. Inert gas supply source 247b, mass flow controller (MFC) 247c and valve 247d may be sequentially arranged from the upstream side in second inert gas supply conduit 247a.

An inert gas may be delivered to gas expanding channel 234 from second inert gas supply conduit 247a, through mass flow controller (MFC) 247c and valve 247d. The inert gas may act as a carrier gas or a dilution gas in the step of forming a film (S203-S207 to mention later).

Second inert gas supply system may include second inert gas supply conduit 247a, mass flow controller (MFC) 247c and valve 247d. In addition, inert gas supply source 247b or second gas supply conduit 244a can be included to the second inert gas supply system.

Furthermore, second gas supply system 244 may include inert gas supply source 247b or the second inert gas supply system.

(Third Gas Supply System)

In third gas supply conduit 245a, third gas supply source 245b, mass flow controller (MFC) 245c and valve 245d may be sequentially arranged from the upstream side.

An inert gas as a purge gas may be supplied from third gas supply source 245b, then, the inert gas may be delivered to gas expanding channel 234 via mass flow controller 245c and valve 245d, through third gas supply conduit 245a and shared gas supply conduit 242.

For example, the inert gas may be nitrogen (N₂) gas. Other than nitrogen (N₂) gas, a rare gas such as helium (He) gas, neon (Ne) gas or argon (Ar) gas etc. may be used.

Third gas supply system 245 may include third gas supply conduit 245a, mass flow controller 245c and valve 245d. Third gas supply system 245 may be called the purge gas supply system.

(Cleaning Gas Supply System)

In cleaning gas supply conduit 248a, cleaning gas supply source 248b, mass flow controller (MFC) 248c, valve 248d and remote plasma unit (RPU) 250 may be sequentially arranged from the upstream side.

A cleaning gas may be supplied from cleaning gas supply source 248b, then, the cleaning gas may be delivered to gas expanding channel 234 via mass flow controller 248c, valve 248d and remote plasma unit (RPU) 250 to activate the cleaning gas, through cleaning gas supply conduit 248a and shared gas supply conduit 242.

The edge of the downstream side of fourth inert gas supply conduit 249a may be coupled with the downstream side from valve 248d arranged in cleaning gas supply conduit 248a. Fourth inert gas supply source 249b, mass flow controller (MFC) 249c and valve 249d may be sequentially arranged from the upstream side in fourth inert gas supply conduit 249a.

Cleaning gas supply system may include cleaning gas supply conduit 248a, mass flow controller (MFC) 248c and valve 248d. In addition, cleaning gas supply source 248b, fourth gas supply conduit 249a or remote plasma unit (RPU) 250 can be included to the cleaning gas supply system.

The inert gas supplied from fourth inert gas supply source 249b may be supplied as a carrier gas or a dilution gas for the cleaning gas.

In cleaning step, the cleaning gas supplied from cleaning gas supply source 248b may act to remove by-products adhering to gas expanding channel 234 or reaction zone 201.

For example, the cleaning gas may be a nitrogen trifluoride (NF3) gas. A hydrogen fluoride (HF) gas, a chlorine trifluoride (ClF3) gas or a fluorine (F2) gas may also be used as the cleaning gas. In addition, these gases may be used in combination as the cleaning gas.

(Controller)

As shown in FIG. 1, substrate processing apparatus 100 includes controller 121 for controlling the operation of each part of substrate processing apparatus 100.

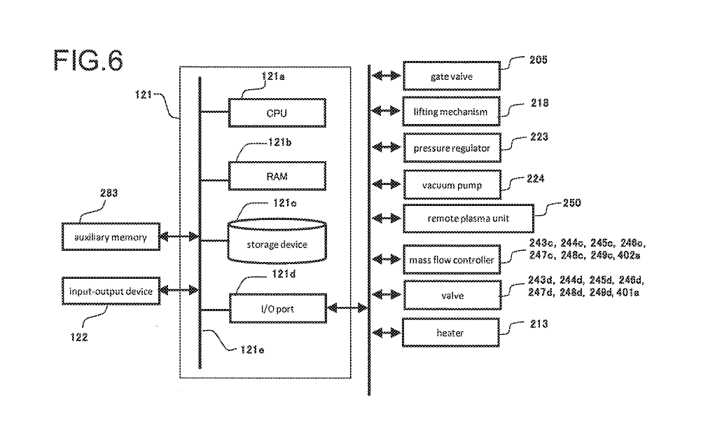

As shown in FIG. 6, controller 121 may be configured as a computer including CPU (Central Processing Unit) 121a, RAM (Random Access Memory) 121b, storage device 121c and I/O port 121d. RAM 121b, storage device 121c, I/O port 121d are constructed so that the exchanges of data with CPU 121 through internal bus 121e are possible. Input-output device 122 which may be configured as a touch panel or auxiliary memory 283 may be coupled to controller 121.

For example, storage device 121c may be to be configured by flash memories or HDD (Hard Disk Drives). In storage device 121c, the control programs to control the operation of the substrate processing apparatus or a process recipe which may include a procedure to process the substrate under some conditions in the substrate processing apparatus may be stored for reading possibility. The process recipe may function as a program which is combination of programs so as to have controller 121 carry out each procedure in the substrate processing process. Hereafter, a program also means a process recipe or a control program collectively. When the terminology “program” is used hereinafter in this specification, the terminology is defined as just the process recipe, the control program or both of them. In addition, RAM 121b may be configured as a memory area (working area) where the program or data read by CPU 121a is held temporarily.

I/O port 121d may works as an input/output port to communicate with gate valve 205, lifting mechanism 218, pressure regulator 223, vacuum pump 224, remote plasma unit (RPU) 250, mass flow controller 243c, 244c, 245c, 246c, 247c, 248c, 249c or 402a, valve 243d, 244d, 245d, 246d, 247d, 258d, 249d or 401a, or heater 213.

CPU 121a may load the program which may be stored in storage device 121c, then execute it. CPU 121a may also load the process recipe corresponding to the operation command input via Input-output device 122. Then, CPU 121a may control the opening/shutting operation at gate valve 205, elevating/lowering operation at lifting mechanism 218, pressure adjustment operation at pressure regulator 223, ON/OFF control at vacuum pump 224, gas excitation operation at remote plasma unit (RPU) 250, flow quantity adjustment operation at mass flow controller 243c, 244c, 245c, 246c, 247c, 248c, 249c or 402a, ON/OFF control at valve 243d, 244d, 245d, 246d, 247d, 258d, 249d or 401a, or temperature control at heater 213.

In addition, controller 121 may constitute it as an exclusive computer and may constitute it as a general-purpose computer. In one embodiment, controller 121 can be constituted by a general-purpose computer which includes auxiliary memory 283 installing above mentioned program. As auxiliary memory 283, there can be a magnetic tape, a magnetic disk such as a flexible disc or a hard disk, optical disk such as a CD or a DVD, a magneto-optical disk such as an MO or a semiconductor memory included in such as a USB memory (USB Flash Drive) or the memory card etc. The means to install the program to a computer are not limited to the means supplying it through auxiliary memory 283. For example, installing the program by using the means of communications such as the Internet or the exclusive line, without auxiliary memory 283, can be possible. In addition, storage device 121c or auxiliary memory 283 are comprised as the recording medium that computer reading is possible. Hereinafter, recording medium means these memories collectively. When the terminology recording medium is used hereinafter in this specification, the terminology is defined as just storage device 121c, auxiliary memory 283 or both of storage device 121c and auxiliary memory 283.

(2) Substrate Processing Process

Forming a silicon nitride (SixNy) film using DCS (Dichlorosilane) gas and NH3 (ammonia) gas is disclosed as an example of the substrate processing process.

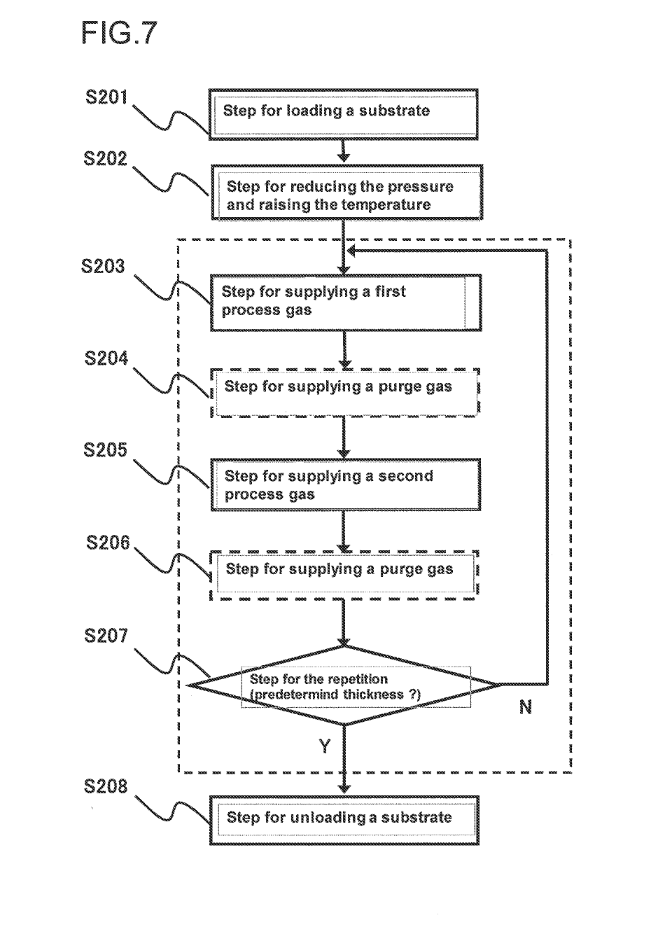

FIG. 7 is a figure of sequence of a substrate processing process employing the substrate processing apparatus according to the embodiment. The figure discloses the steps for forming a silicon nitride (SixNy) film on wafer 200 as a substrate.

(Step for Loading a Substrate S201)

In the process for forming a film, firstly, wafer 200 is transferred to reaction zone 201. Specifically, substrate setting tray 212 is moved down to the position for transferring the substrate, upper end portions of lift pins 207 protrude from substrate receiving surface 211 so that lift pins 207 can support wafer 200 from below. After adjusting the pressure in reaction zone 201 to predetermined pressure, gate valve 205 is open, then, wafer 200 is moved on lift pins 207 through gate valve 205 from the outside of process chamber 202 using wafer transfer robot (not illustrated). After setting wafer 200 on lift pins 207, substrate setting tray 212 is moved up to the predetermined position using lifting mechanism 218 under supplying an inert gas from third gas supply system 245, for setting the substrate on substrate receiving surface 211. Substrate setting tray 212 is further moved up to the process position shown in FIG. 1, where projecting part 212b of substrate setting tray 212 comes into contact with partition plate 204. A purge gas may be supplied to the generated gap between projecting part 212b of substrate setting tray 212 and partition plate 204, from the purge gas supply system. The purge gas may be supplied to contact area 500L under the condition that projecting part 212b of substrate setting tray 212 comes into contact with partition plate 204. The purge gas may also be supplied to the space generated between projecting part 212b of substrate setting tray 212 and partition plate 204 under the condition that projecting part 212b of substrate setting tray 212 is close to partition plate 204. In addition, it is preferable that supplying the purge gas is performed at least during the period that the first gas or the second gas is supplying to process chamber 202, disclosed in detail later.

(Step for Reducing the Pressure and Raising the Temperature S202)

Then, controller 121 may control exhaust system 220 to evacuate reaction zone 201 through exhaust conduit 222 so that the pressure in reaction zone 201 becomes predetermined vacuum (degree of vacuum). In this case, the divergence of valve of APC as pressure regulator 223 may be controlled by feeding back the pressure detected by the pressure sensor. In addition, controller 121 may control the flow amount of electricity to heater 213 based on the temperature detected by the temperature sensor (not illustrated) for reaction zone 201, so that the temperature in reaction zone 201 becomes the predetermined temperature. More specifically, substrate receiving surface 211 on substrate setting tray 212 may be heated beforehand. Thus, wafer 200 may be put on the substrate receiving surface 211 for a while. Then, the temperature of wafer 200 or substrate receiving surface 211 becomes stable, from 300 degrees Celsius to 650 degrees Celsius, preferably from 300 degrees Celsius to 600 degrees Celsius, more preferably from 300 degrees Celsius to 550 degrees Celsius. Meanwhile, the water or its ingredients remaining in reaction zone 201 or gases clinging to the materials constituting reaction zone 201 may also be reduced by exhausting reaction zone 201 for a vacuum, or by supplying a purge gas to reaction zone 201. The preparations before forming a film may be completed in these procedures. In addition, when reaction zone 201 is exhausted to the predetermined pressure, it may be exhausted to an accessible best vacuum degree. In this case, supplying a purge gas to contact area 500L from partitioning gas system 300 may start after reaching an accessible best vacuum degree by exhausting.

(Step for Supplying a First Process Gas S203)

Next, DCS (Dichlorosilane) gas as the first process gas (the source gas) may be supplied to reaction zone 201 from first gas supply system 243 as shown in FIG. 7. Controller 121 may also control the exhausting reaction zone 201 so that the pressure in reaction zone 201 becomes the predetermined pressure. Specifically, valve 243d in first gas supply conduit 243a and valve 246d in first inert gas supply conduit 246a may be open, then DCS (Dichlorosilane) gas may flow through first gas supply conduit 243a and N2 (Nitrogen) gas may flow through first inert gas supply conduit 246a. The flow rate of the DCS gas in first gas supply conduit 243a may be controlled by mass flow controller 243c and the flow rate of the N2 gas in first inert gas supply conduit 246a may be controlled by mass flow controller 246c. The DCS gas may be mixed with the N2 gas in first gas supply conduit 243a, DCS gas mixed with N2 gas may be supplied to reaction zone 201 through gas expanding channel 234, then these gases may be exhausted through exhaust conduit 222. In this way, the main surface of wafer 200 on substrate receiving surface 211 may be exposed to the DCS gas (Step for supplying a first process gas). The DCS gas as the first process gas may be supplied to reaction zone 201 under predetermined pressure, for example less than 10,000 Pa more than 100 Pa. In this way, a layer containing silicon may be formed on wafer 200, by exposing the main surface of wafer 200 to the DCS gas.

The layer containing silicon means a layer containing silicon (Si), or a layer containing silicon (Si) and chlorine (Cl). At least in this step, a purge gas may be supplied to the generated gap between projecting part 212b of substrate setting tray 212 and partition plate 204, from the purge gas supply system. The purge gas may be supplied to contact area 500L under the condition that projecting part 212b of substrate setting tray 212 comes into contact with partition plate 204.

(Step for Supplying a Purge Gas S204)

After forming a layer containing silicon on wafer 200, supplying the DCS gas may be stopped by closing valve 243d in first gas supply conduit 243a. In this procedure, by maintaining the state that pressure regulator 223 in exhaust conduit 222 may be opened, the excess gases which include the DCS gas which is not adhering or adsorbing the surface of wafer 200, or the gases generated by the decomposition, may be exhausted from reaction zone 201 by employing vacuum pomp 224. In addition, valve 246d may be opened, N2 gas as an inert gas may be delivered to reaction zone 201. N2 gas delivered through valve 246a may act as a purge gas, thus the excess gases which remain in first gas supply conduit 243a, shared gas supply conduit 242 or reaction zone 201 can be removed effectively.

In this procedure, it may be not necessary that the excess gas in gas expanding channel 234 or reaction zone 201 etc. is purged completely. After the step for supplying the purge gas, if the gas remaining in reaction zone 201 is a small amount, it does not become the problem substantially in the later process. It is not necessary that the delivering volume of N2 gas as a purge gas is high. For example, delivering the N2 gas to the reaction zone 201 at the same level as the capacity of reaction zone 201, it can be purged so as not to become the problem substantially in the later process. In this way, purge time can be shorten and improve throughput commercially by not purging completely in reaction zone 201. In addition, the consumption of N2 gas can be able to suppress.

In this procedure, controller 121 may control the flow amount of electricity to heater 213 based on the temperature detected by the temperature sensor (not illustrated) for reaction zone 201, so that the temperature in reaction zone 201 is maintained in the predetermined range like the step for supplying the first process gas. More specifically, the temperature of wafer 200 or substrate receiving surface 211 is maintained from 300 degrees Celsius to 650 degrees Celsius, preferably from 300 degrees Celsius to 600 degrees Celsius, more preferably from 300 degrees Celsius to 550 degrees Celsius. The flow rate of N2 gas, delivered from each of the inert gas supply system may be set in the range from 100 to 20,000 sccm. For example, the purge gas may be nitrogen (N₂) gas. Other than nitrogen (N₂) gas, a rare gas such as helium (He) gas, neon (Ne) gas, argon (Ar) gas or xenon (Xe) gas etc. may be used.

(Step for Supplying a Second Process Gas S205)

After exhausting excess gases in reaction zone 201, delivering the purge gas may be stopped, then NH3 (ammonia) gas as a second process gas may be supplied to reaction zone 201. Specifically, valve 244d in second gas supply conduit 244a and valve 247d in second inert gas supply conduit 247a may be open, then NH3 (ammonia) gas may flow through second gas supply conduit 244a and N2 (Nitrogen) gas may flow through second inert gas supply conduit 247a. The flow rate of the NH3 gas in second gas supply conduit 244a may be controlled by mass flow controller 244c and the flow rate of the N2 gas in second inert gas supply conduit 247a may be controlled by mass flow controller 247c. The NH3 gas may be mixed with the N2 gas in second gas supply conduit 244a, NH3 gas mixed with N2 gas may be supplied to reaction zone 201 through gas expanding channel 234, then these gases may be exhausted through exhaust conduit 222. In this way, the layer containing silicon, formed on the main surface of wafer 200 at the step for supplying the first process gas S203, may be exposed NH3 gas, thus silicon molecules in the layer or on the layer may be reacted with nitrogen molecules. Then, the impurities such as hydrogen, chlorine, the hydrogen chloride may be exhausted.

At least in this step, a purge gas may be supplied to the generated gap between projecting part 212b of substrate setting tray 212 and partition plate 204, from the purge gas supply system. The purge gas may be supplied to contact area 500L under the condition that projecting part 212b of substrate setting tray 212 comes into contact with partition plate 204.

(Step for Supplying a Purge Gas S206)

After the step for supplying a second process gas S205, supplying the NH3 gas may be stopped by closing valve 244d in second gas supply conduit 244a. In this procedure, by maintaining the state that pressure regulator 223 in exhaust conduit 222 may be opened, the excess gases which include the NH3 gas which did not contribute to nitriding of the layer containing silicon, or the gases generated by the decomposition, may be exhausted from reaction zone 201 by employing vacuum pomp 224. In addition, valve 247d may be opened, N2 gas as an inert gas may be delivered to reaction zone 201. N2 gas delivered through valve 247a may act as a purge gas, thus the excess gases which remain in second gas supply conduit 244a, shared gas supply conduit 242 or reaction zone 201 can be removed effectively. By exhausting excess gases from reaction zone 201, forming an unexpected film in reaction zone 201 can be controlled.

(Step for the Repetition S207)

A silicon nitriding (SixNy) layer of predetermined thickness may be deposited on wafer 200 by performing above-mentioned the step for supplying a first process gas S203, the step for supplying a purge gas S204, the step for supplying a second process gas S205, and the step for supplying a purge gas S206. The film thickness of the silicon nitride film may be controlled by repeating these steps. Controller 121 may control the repeating number of these steps so as to get the predetermined film thickness.

(Step for Unloading a Substrate S208)

After the step for the repetition S207, wafer 200 may be transferred from reaction zone 201 by executing the step for unloading a substrate S208. Specifically, the temperature of wafer 200 may be lowered to the temperature so as to be able to move wafer 200 from substrate receiving surface 211 apart. Transfer zone 203 may be purged by an inert gas, and the pressure in transfer zone 203 may be regulated so that wafer 200 can transfer from the inside of transfer zone 203 to the outside of it. After the pressure in transfer zone 203 becomes stable, by lowering substrate supporting member 210 using lifting mechanism 218, wafer 200 may be supported on lift pins 207 protruding from substrate receiving surface 211. After supporting wafer 200 on lift pins 207, gate valve 205 may be open, then wafer 200 may be moved from transfer zone 203.

In addition, by raising the pressure in transfer zone 203 than the pressure in reaction zone 201 while the purge gas is supplying to contact area 500L, a gas leak from reaction zone 201 to transfer zone 203 may be reduced.

### (3) Effects in these Embodiments

For example, one or more effects in these embodiments are shown below.

(a) As projecting part 212b of substrate setting tray 212 comes into contact with partition plate 204a, a gas leak from reaction zone 201 to transfer zone 203 may be reduced.
(b) As delivering a purge gas to gap 500g formed between projecting part 212b of substrate setting tray 212 and partition plate 204a, a gas leak from reaction zone 201 to transfer zone 203 may be reduced even supplying process gases to reaction zone 201 like a pulse flow.
(c) As delivering a purge gas to gap 500g formed between projecting part 212b of substrate setting tray 212 and partition plate 204a, a gas leak from reaction zone 201 to transfer zone 203 may be reduced even supplying process gases to reaction zone 201 like a flush flow.

### Other Embodiments of Present Disclosure

It will be understood by those of skill in the art that numerous and various modifications can be made without departing from the spirit of the present disclosure. Therefore, it should be clearly understood that the forms of the present disclosure are illustrative only and are not intended to limit the scope of the present disclosure.

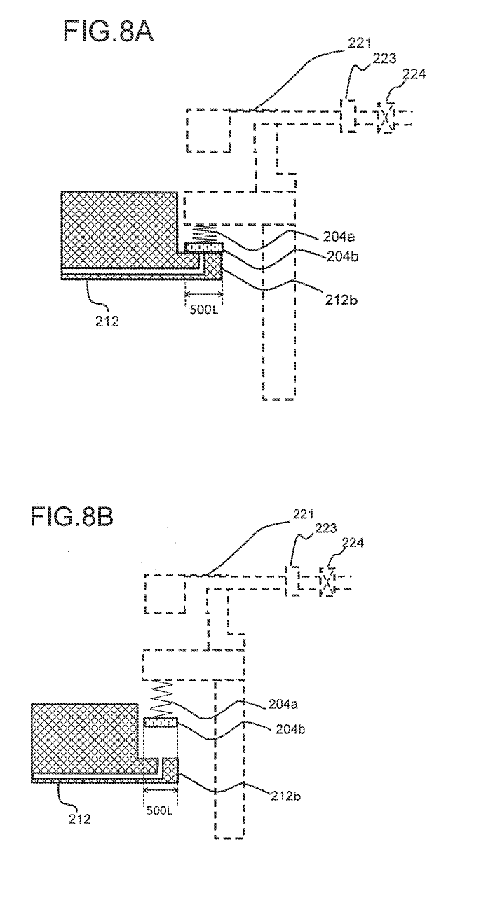

FIG. 8A or FIG. 8B is a schematic view showing positional relation of substrate setting tray 212 and partitioning plate 204 under processing or transferring wafer 200 according to another embodiment of the present disclosure. As shown in FIG. 8A or FIG. 8B, partition plate 204 includes flexible part 204a and contact part 204b. For example, flexible part 204a may consist of bellows and contact part 204b may be comprised of materials same as substrate setting tray 212. FIG. 8A is a schematic view showing positional relation of substrate setting tray 212 and partitioning plate 204 under processing wafer 200. FIG. 8B is a schematic view showing positional relation of substrate setting tray 212 and partitioning plate 204 under transferring wafer 200. As shown in FIG. 8B, projecting part 212b extending outward from substrate setting tray 212 in the radial direction may not contact with contact part 204b under transferring wafer 200, flexible part 204a may be in a condition to have lengthened. As shown in FIG. 8A, projecting part 212b extending outward from substrate setting tray 212 in the radial direction may contact with contact part 204b under processing wafer 200, flexible part 204a may be in a condition to have shrunk. In these configurations, uniform contact of projecting part 212b and partitioning plate 204 in the circumferential direction may be secured even if the condition that horizontal alignment is insufficient. Therefore, it is possible that a parallel degree of projecting part 212b and partitioning plate 204 can maintain, then the length of contact area 500L and the vertical width of gap 500g can be kept in the circumferential direction.

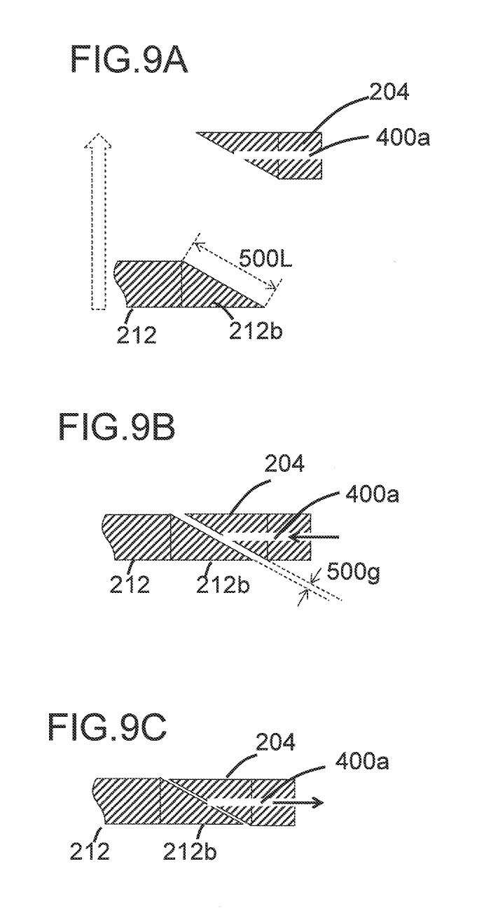

FIG. 9A to 9C are schematic views showing positional relation of substrate setting tray 212 and partitioning plate 204 under processing or transferring wafer 200 according to another embodiment of the present disclosure. It is preferable that the contact shape of substrate setting tray 212 and partitioning plate 204 in sectional view is a wedge shape or a tapered shape so that the conductance of gap 500g becomes low and substrate setting tray 212 can move up and down between positions for processing wafer 200 and transferring wafer 200 in the vertical direction. For example, projecting part 212b may be projected from side wall 212a of substrate setting tray 212, tapered away to the edge of outside, being corresponded to the tapered partition plate 204 as shown in FIG. 9A. FIG. 9A shows a positional relation of substrate setting tray 212 and partitioning plate 204 under the condition that wafer 200 is transferring. Substrate setting tray 212 may be raise up to the position for processing the substrate in the direction of the block arrow as shown in FIG. 9A. Then, the tapered part of projecting part 212b may come into contact with the corresponding tapered part of partition plate 204 as shown in FIG. 9B. According to this configuration, as the length of contact area 500L between partition plate 204 and projecting part 212b can get longer than the length of the contact area if partition plate 204 comes into contact with projecting part 212b perpendicularly. Thus, the exhaust conductance of gap 500g can become low, then, gas flow between reaction zone 201 and transfer zone 203 for processing the substrate can become hard. Therefore, the gas leak between reaction zone 201 and transfer zone 203 for processing the substrate can be reduced. Since the exhaust conductance of gap 500g becomes low, when the pressure in reaction zone 201 is lower than the pressure in transfer zone 203 by exhausting reaction zone 201 for a vacuum, the gas flow between transfer zone 203 and reaction zone 201 can be reduced. Therefore, it is restrained that the byproducts or particles including metallic materials existing in transfer zone 203 flow into reaction zone 201. Furthermore, by supplying a purge gas to gap 500g through purge gas supply conduit 400a, as shown it with an arrow in FIG. 9B, the gas flow between transfer zone 203 and reaction zone 201 can be reduced more effectively. In addition, by exhausting a gas from gap 500g through purge gas supply conduit 400a, as shown it with an arrow in FIG. 9C, a vacuum degree in gap 500g may be improved, then partition plate 204 may come into contact with projecting part 212b more strongly by the effect of the vacuum adsorption. Thus, the gas flow between transfer zone 203 and reaction zone 201 can be reduced.

In another embodiment, a substrate processing apparatus for forming a refractory metal layer employing at least bifurcated deposition process and a method for forming a refractory metal layers employing at least bifurcated deposition process are disclosed.

In this embodiment, for example, the refractory metal is selected from the group consisting of titanium (Ti) and tungsten (W).

The gas containing first element (first process gas) may be one of process gases including a source gas or a precursor gas. For example, the first element is tungsten (W). That is to say, the first process gas may be the gas containing tungsten (W). Tungsten hexafluoride (WF6) gas can be adapted to the gas containing tungsten. Tungsten hexafluoride (WF6) gas may be supplied from first gas supply conduit 243a with a first carrier gas.

The second gas maybe the gas containing boron (B). Diborane (B2H6) gas can be adapted to the gas containing boron. Diborane (B2H6) gas may be supplied from second gas supply conduit 244a with a second carrier gas.

Hydrogen (H2) gas may be used as the first carrier gas for the tungsten hexafluoride (WF6) gas. In addition, the first carrier gas can be selected from a group of hydrogen (H2), nitrogen (N₂), helium (He), neon (Ne), argon (Ar), and combinations thereof.

Hydrogen (H2) gas may be used as the second carrier gas for the diborane (B2H6) gas. In addition, the second carrier gas can be selected from a group of hydrogen (H2), nitrogen (N₂), helium (He), neon (Ne), argon (Ar), and combinations thereof.

Argon (Ar) gas as a first purge gas may be supplied from third gas supply source 245b, then, the first purge gas may be delivered to gas expanding channel 234 via mass flow controller 245c and valve 245d, through third gas supply conduit 245a and shared gas supply conduit 242.

Argon (Ar) gas maybe used as the first purge gas for reaction zone 201. In this embodiment, the first purge gas can be selected from a group of nitrogen (N₂), helium (He), neon (Ne), argon (Ar), and combinations thereof.

A second purge gas may be supplied to the generated gap between projecting part 212b of substrate setting tray 212 and partition plate 204, from the purge gas supply system. The second purge gas may be supplied to contact area 500L under the condition that projecting part 212b of substrate setting tray 212 comes into contact with partition plate 204. The second purge gas may also be supplied to the space generated between projecting part 212b of substrate setting tray 212 and partition plate 204 under the condition that projecting part 212b of substrate setting tray 212 is close to partition plate 204. In addition, it is preferable that supplying the second purge gas is performed at least during the period that the first gas or the second gas is supplying to process chamber 202.

Argon (Ar) gas may be used as the second purge gas for reaction zone 201. In this embodiment, the first purge gas can be selected from a group of nitrogen (N₂), helium (He), neon (Ne), argon (Ar), and combinations thereof.

Forming a refractory metal film using tungsten hexafluoride (WF6) and diborane (B2H6) is disclosed as another embodiment of the substrate processing process. FIG. 7 is a figure of sequence of a substrate processing process employing the substrate processing apparatus according to another embodiment. The figure also discloses the steps for forming a refractory metal film on wafer 200. As for the steps like the steps for a silicon nitride (SixNy) film explained earlier, explanations are omitted.

In the Step for supplying a first process gas S203 in FIG. 7, tungsten hexafluoride (WF6) gas as the first process gas may be supplied to reaction zone 201 from first gas supply system 243. Hydrogen (H2) gas may be used as the first carrier gas for the tungsten hexafluoride (WF6) gas. Controller 121 may control the exhausting reaction zone 201 so that the pressure in reaction zone 201 becomes the predetermined pressure. At least in this step, argon (Ar) gas as a purge gas may be supplied to the generated gap between projecting part 212b of substrate setting tray 212 and partition plate 204, from the purge gas supply system. The purge gas may be supplied to contact area 500L under the condition that projecting part 212b of substrate setting tray 212 comes into contact with partition plate 204. In this embodiment, the carrier gas for tungsten hexafluoride (WF6) may differ from the purge gas delivering to contact area 500L.

In the Step for supplying a second process gas S205 in FIG. 7, diborane (B2H6) gas as the second process gas may be supplied to reaction zone 201 from second gas supply system 244. Hydrogen (H2) gas may be used as the second carrier gas for the diborane (B2H6) gas. Controller 121 may control the exhausting reaction zone 201 so that the pressure in reaction zone 201 becomes the predetermined pressure. At least in this step, argon (Ar) gas as a purge gas may be supplied to the generated gap between projecting part 212b of substrate setting tray 212 and partition plate 204, from the purge gas supply system. The purge gas may be supplied to contact area 500L under the condition that projecting part 212b of substrate setting tray 212 comes into contact with partition plate 204. In this embodiment, the carrier gas for diborane (B2H6) may differ from the purge gas delivering to contact area 500L.

In this embodiment, by employing Hydrogen (H2) gas as the first carrier gas or the second carrier gas, the concentration of fluorine in a refractory metal layer can be lowered, and employing an inert gas like argon (Ar) gas as a purge gas for gap 500g, gas leak between reaction zone 201 and transfer zone 203 can be reduced effectively, and an unexpected chemical reaction with a residual gas in process chamber 202 can be reduced in comparison with employing Hydrogen (H2) gas as a purge gas.

Pursuant to the present disclosure, the substrate processing apparatus may be applicable to the apparatus for manufacturing a liquid crystalline device or a ceramic substrate.

Pursuant to the present disclosure, the process which the first process gas and the second process gas are supplied alternately is disclosed. Furthermore, the process may be applicable to the process that the supply timing of first process gas overlaps with the second process gas.

Furthermore, the process may be applicable to the process that the first process gas and the second process gas are supplied to reaction zone 201 concurrently as a chemical vapor deposition (CVD) process.

Pursuant to the present disclosure, the process may be applicable to the process that at least one of the first process gas or the second process gas may be excited by plasma. In this case, plasma exciter may be added to at least one of first gas supply conduit 243a or second gas supply conduit 244a. Such a substrate processing apparatus including plasma exciter may be applicable to the apparatus for the plasma oxidizing, plasma nitriding or plasma annealing.

Hereinafter, preferred embodiments of the present disclosure will be appended.

(Supplementary Note 1) Pursuant to the present disclosure, there is provided a substrate processing apparatus including a reaction zone configured to accommodate a substrate, a substrate supporting member having a projecting part extending outward, a partition plate configured to partition off the reaction zone and a transferring zone, coming in contact with the projecting part of the substrate supporting member when the substrate is processed, a process gas supplying system configured to supply a process gas to the reaction zone and a partitioning purge gas supplying system configured to supply a purge gas to a gap formed between the projecting part and the partition plate when supplying the process gas to the substrate.

(Supplementary Note 2) In the substrate processing apparatus of Supplementary Note 1, a vertical distance between the projecting part and the partition plate is shorten than a radial distance of the projecting part coming in contact with the partition plate under a substrate processing state.

(Supplementary Note 3) In the substrate processing apparatus of Supplementary Note 1 or Note 2, the substrate processing apparatus further includes a controller configured to control the substrate supporting member and the purge gas supplying system so that the purge gas supplying system supplies the purge gas to the gap formed between the projecting part and the partition plate after the projecting part came in contact with partition plate.

(Supplementary Note 4) In the substrate processing apparatus of any one of Supplementary Notes 1 through Note 3, the substrate processing apparatus further includes an inert gas supplying system configured to supply an inert gas to the substrate and a controller configured to control the substrate supporting member, the partitioning purge gas supplying system, the process gas supplying system and the inert gas supplying system so as to perform the following steps:

(a) supplying the inert gas to the reaction zone when the substrate supporting member is elevated to the position for processing;
(b) supplying the purge gas to the gap formed between the projecting part and the partition plate after the projecting part came in contact with partition plate;
(c) supplying the process gas to the reaction zone after supplying the purge gas.

(Supplementary Note 5) In the substrate processing apparatus of Supplementary Note 1, the partitioning purge gas supplying system is configured to supply a purge gas continuously to a gap formed between the projecting part and the partition plate during supplying the process gas to the substrate.

(Supplementary Note 6) Pursuant to the present disclosure, there is also provided a method of manufacturing a semiconductor device, the method includes accommodating a substrate in a reaction zone, supporting the substrate by employing a substrate supporting member having a projecting part extending outward and supplying a purge gas to a gap formed between the projecting part and a partition plate configured to partition off the reaction zone and a transferring zone, coming in contact with the projecting part of the substrate supporting member when the substrate is processed.

(Supplementary Note 7) In the method of manufacturing a semiconductor device of Supplementary Note 6, the method further includes elevating the substrate supporting member to the position for processing from the transferring zone, supplying an inert gas to the reaction zone in the step of elevating the substrate supporting member to the position for processing and supplying a process gas to the substrate after supplying the purge gas to the gap formed between the projecting part and the partition plate.

(Supplementary Note 8) In the method of manufacturing a semiconductor device of Supplementary Note 6 or Note 7, the method further includes supplying a purge gas to a gap formed between the projecting part and a partition plate performs continuously during supplying the process gas to the reaction zone.

(Supplementary Note 9) Pursuant to the present disclosure, there is also provided a program for manufacturing a semiconductor device by employing a substrate processing apparatus, the program causing the substrate processing apparatus to execute accommodating a substrate in a reaction zone, supporting the substrate by employing a substrate supporting member having a projecting part extending outward and supplying a purge gas to a gap formed between the projecting part and a partition plate configured to partition off the reaction zone and a transferring zone, coming in contact with the projecting part of the substrate supporting member when the substrate is processed.

(Supplementary Note 10) In the program of Supplementary Note 9, the program further causing the substrate processing apparatus to execute elevating the substrate supporting member to the position for processing from the transferring zone, supplying an inert gas to the reaction zone in the step of elevating the substrate supporting member to the position for processing and supplying a process gas to the substrate after supplying the purge gas to the gap formed between the projecting part and the partition plate.

(Supplementary Note 11) In the program of Supplementary Note 9 or Note 10, the program further causing the substrate processing apparatus to execute supplying a purge gas to a gap formed between the projecting part and a partition plate continuously during supplying the process gas to the reaction zone.

(Supplementary Note 12) Pursuant to the present disclosure, there is also provided a non-transitory computer-readable recording medium storing a program for manufacturing a semiconductor device by employing a substrate processing apparatus, the program causing the substrate processing apparatus to execute accommodating a substrate in a reaction zone, supporting the substrate by employing a substrate supporting member having a projecting part extending outward and supplying a purge gas to a gap formed between the projecting part and a partition plate configured to partition off the reaction zone and a transferring zone, coming in contact with the projecting part of the substrate supporting member when the substrate is processed.

(Supplementary Note 13) In the non-transitory computer-readable recording medium storing a program for manufacturing a semiconductor device of Supplementary Note 12, the program further causing the substrate processing apparatus to execute elevating the substrate supporting member to the position for processing from the transferring zone, supplying an inert gas to the reaction zone in the step of elevating the substrate supporting member to the position for processing and supplying a process gas to the substrate after supplying the purge gas to the gap formed between the projecting part and the partition plate.

(Supplementary Note 14) In the non-transitory computer-readable recording medium storing a program for manufacturing a semiconductor device of Supplementary Note 13, the program further causing the substrate processing apparatus to execute supplying a purge gas to a gap formed between the projecting part and a partition plate continuously during supplying the process gas to the reaction zone.

### DESCRIPTION OF SIGNS AND NUMERALS

100 Substrate processing apparatus
200 Wafer (Substrate)
201 Reaction zone
202 Process chamber
203 Transferring zone
204 Partition plate
210 Substrate supporting member
212 Substrate setting tray
212b Projecting part
213 Heater
221 Exhausting port
234 Gas expanding channel
231 Lid
243 First gas supply system
244 Second gas supply system
250 Remote plasma unit (Excitation unit)
301a Purge gas supply path
301b Purge gas supply groove

1. A substrate processing apparatus comprising:
a reaction zone configured to accommodate a substrate;
a substrate setting tray having a projecting part extending outward;
a partition plate configured to partition off the reaction zone and a transferring zone, and coming in contact with the projecting part of the substrate setting tray when the substrate is processed;
a process gas supplying system configured to supply a process gas to the reaction zone; and
a partitioning gas system configured to supply a purge gas to a gap formed between the projecting part and the partition plate when supplying the process gas to the substrate.

2. The substrate processing apparatus according to claim 1, wherein a vertical width of the gap between the projecting part and the partition plate is shorter than a radial distance of the projecting part coming in contact with the partition plate under a substrate processing state.

3. The substrate processing apparatus according to claim 1, further comprising:
a controller configured to control the partitioning gas system so that the purge gas is delivered to the gap at least when the projecting part comes into contact with the partition plate or close to the partition plate.

4. The substrate processing apparatus according to claim 1, further comprising:
an inert gas supplying system configured to supply an inert gas to the substrate; and
a controller configured to control a substrate supporting member, the partitioning gas system, the process gas supplying system and the inert gas supplying system so as to perform the following steps:
(a) supplying the inert gas to the reaction zone when the substrate supporting member is elevated to a position for processing;
(b) supplying the purge gas to the gap formed between the projecting part and the partition plate after the projecting part comes in contact with partition plate;
(c) supplying the process gas to the reaction zone after supplying the purge gas.

5. The substrate processing apparatus according to claim 1, wherein the partitioning gas system configured to supply a purge gas continuously to a gap formed between the projecting part and the partition plate during supplying of the process gas to the substrate.

6. The substrate processing apparatus according to claim 1, wherein the partitioning gas system having a buffer groove, being connected to a purge gas supply path via an additional supply path, the buffer groove having an opening facing to a contact area between the projecting part and the partition plate, and a width of the opening in a radial direction is wider than a width of the additional supply path, but within a width of the contact area.

7. The substrate processing apparatus according to claim 1, wherein the partitioning gas system having a buffer groove in the projecting part, being connected to a purge gas supply path via an additional supply path in the substrate setting tray, the buffer groove having an opening facing to a contact area between the projecting part and the partition plate, and a width of the opening in a radial direction is wider than a width of the additional supply path, but within a width of the contact area.

8. The substrate processing apparatus according to claim 1, wherein the partition plate includes a flexible part including bellows, and a contact part.

9. A substrate processing apparatus comprising:
a process chamber configured to be an airtight container to accommodate a substrate in a state when a principal plane of a substrate is horizontal, and including an upper part container and a lower part container;
a partition plate disposed between the upper part container and the lower part container;
a substrate setting tray having a projecting part extending outward from the substrate setting tray in a radial direction, having a substrate receiving surface on a top surface thereof, supported by a shaft connected with a lifting mechanism;
a gas expanding channel connected to the upper part container, having a tapered bottom surface, being shaped and sized to substantially cover a substrate on a substrate receiving surface;
a process gas supply system connected to the gas expanding channel;
an exhaust port arranged at a side wall of the upper part container, and being located to the outside in a horizontal direction, and beyond a connected part between the substrate setting tray and the partition plate when the substrate setting tray comes into contact with the partition plate when the substrate setting tray is located at a position for processing substrate using the lifting mechanism; and
a partitioning gas system for delivering a purge gas to a gap between the projecting part and the partition plate

10. The substrate processing apparatus according to claim 9, wherein a vertical width of the gap between the projecting part and the partition plate is shorter than a radial distance of the projecting part coming in contact with the partition plate under a substrate processing state.

11. The substrate processing apparatus according to claim 10, wherein a contact shape of the substrate setting tray and the partitioning plate in sectional view is a wedge or tapered shape so that the substrate setting tray can move up and down between positions for processing or transferring a substrate in a vertical direction.

12. The substrate processing apparatus according to claim 11, further comprising:
a controller configured to control the partitioning gas system so that the purge gas is delivered to the gap at least when the projecting part comes into the contact with the partition plate or close to the partition plate.

13. The substrate processing apparatus according to claim 12, wherein the process gas supply system including a first gas supply system and a second gas supply system, the controller configured to further control the process gas supply system so that the first gas and the second gas are delivered to the upper part container alternately.

14. The substrate processing apparatus according to claim 13, wherein the first gas is tungsten hexafluoride gas and the second gas is diborane gas.

15. The substrate processing apparatus according to claim 14, wherein at least one of the first gas or the second gas is carried by hydrogen, and the purge gas delivered to the gap between the projecting part and the partition plate is a gas selected from a group consisting of nitrogen, helium, neon, argon, and combinations thereof.

16. The substrate processing apparatus according to claim 13, wherein at least one of the first gas or the second gas is fluorine-containing gas, at least one of the first gas or the second gas is carried by hydrogen, and the purge gas delivered to the gap between the projecting part and the partition plate is a gas selected from a group consisting of nitrogen, helium, neon, argon, and combinations thereof.
